(19) United States
(12) Patent Application Publication
(10) Pub. No.: US 2005/0239289 A1
(43) Pub. Date: Oct. 27, 2005

(54) Method for reducing integrated circuit defects

(76) Inventors: Nilesh S. Doke, Dallas, TX (US); Chad J. Kaneshige, McKinney, TX (US); John E. Campbell, Plano, TX (US); Eric D. Simms, Rowlett, TX (US); Manoj K. Jain, Plano, TX (US)

Correspondence Address: TEXAS INSTRUMENTS INCORPORATED, P O BOX 655474, M/S 3999, DALLAS, TX, 75265, US

(21) Appl. No.: 11/159,772

(22) Filed: Jun. 23, 2005

Related U.S. Application Data
(62) Division of application No. 10/610,414, filed on Jun. 30, 2003.

(51) Int. Cl. H01L 21/302; B44C 1/22

(52) U.S. Cl. 438/692; 216/88; 134/2

(57) ABSTRACT

Post chemical mechanical polishing (CMP) cleaning methods are disclosed which reduce integrated circuit defects. A corrosion inhibitor is preferably applied during the post-CMP cleaning steps after application of a first chemistry. Subsequent to the application of the corrosion inhibitor a rinsing step using deionized water is employed. In this manner, the corrosion inhibitor applied during the post-CMP clean fills voids created in previous passivation layers by previous chemistries. Also, existing post-CMP equipment may be used to implement the preferred embodiments of the present invention. Preferably the corrosion inhibitor applied during the post-CMP clean is benzotriazole (BTA).

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND OF THE INVENTION

1. Technical Field of the Invention

The present invention relates generally to the preparation of integrated circuits on semiconductor substrates such as silicon wafers and more particularly to methods for reducing defects using enhanced post-CMP cleaning.

2. Description of Related Art

The semiconductor technology central to the modern integrated circuit has been developing for over a century. In the late nineteenth century, the special properties of the semiconductor selenium were first observed and recognized. The field of semiconductor physics advanced rapidly and the first transistor was proposed in the 1930s. However, not until the late 1940s was a functional point contact transistor constructed. The integrated circuit, which employs a plurality of circuit elements in a monolithic semiconductor substrate rather than using discrete components, was first developed in the late 1950s by Jack Kilby at Texas Instruments, Inc. and by Robert Noyce at Fairchild Semiconductor Corporation.

Since the late 1950s, integrated circuit technology has evolved rapidly and has revolutionized virtually every industry and capacity in which integrated circuits are used. Today's integrated circuits frequently employ hundreds of thousands or even millions of transistors and highly complex, multi-layered architectures. The proliferation of electronics in general, and integrated circuits in particular, has resulted in large part from the ability to increase circuit functionality while simultaneously reducing device cost and size. An important catalyst for these improvements has been advances in semiconductor processing technologies, the various techniques used to construct circuit elements—e.g., transistors, resistors and capacitors—on the semiconductor substrate, as well as the necessary conducting interconnects between individual circuit elements. Improved materials, equipment and processes have allowed increasingly complex circuits having improved speed, reduced power requirements and a smaller footprint.

Integrated circuits are typically constructed at the surface of a crystalline silicon wafer, although other semiconductors such as gallium arsenide and germanium are also used. The individual circuit elements are formed in and on the wafer surface. The electrical conduction between appropriate circuit elements, and electrical isolation between other circuit elements, is then established using alternating layers of appropriately patterned conductors and insulators. The circuit elements and their interconnections are formed using a series of processing steps including photolithography, thin film deposition, selective etching and ion implantation, as well as various cleaning processes.

Increasingly complex integrated circuits utilize an increasing number of circuit elements, which in turn requires both more electrical conduction paths between circuit elements and a greater number of conductor-insulator layers to achieve these paths. This has proved problematic for several reasons. First, longer interconnect paths means increasing resistance and capacitance, which not only decreases circuit speed by increasing RC-delay times but also increases resistive power loss. Second, an increasing number of layers makes successive layer-to-layer alignment more difficult. This latter problem is compounded by layers that lack global and local planarity. Historically, the techniques available to improve layer planarity in the semiconductor industry have been quite limited.

Until recently, aluminum was the interconnect conductor of choice in integrated circuit processing. Techniques for depositing thin aluminum films are well established and, because aluminum trichloride is somewhat volatile, aluminum can be etched effectively in chlorine plasmas to form patterned aluminum films following appropriate photolithography steps. At the same time, aluminum interconnects have several undesirable properties. First, aluminum is not a particularly good conductor: its resistivity is considerably higher than many other metals. Second, aluminum is particularly susceptible to electromigration, the physical movement of a conductor due to electron flow. Electromigration at grain boundaries results in conductor discontinuities and reduced circuit reliability.

The semiconductor industry is transitioning from aluminum to copper as the electrical conductor of choice for establishing interconnections between circuit elements. Copper has a significantly higher conductivity than aluminum and is inherently more resistant to electromigration. Although these properties of copper have been known for a long time, the absence of acceptable methods for selectively etching or otherwise removing copper have limited its use: unlike aluminum, copper is not amenable to plasma etch. Thus, a key limitation in moving to copper metallization is the ability to etch or otherwise remove copper at the wafer surface.

The shift to copper metallization is being driven by the development of chemical mechanical polishing (CMP), a relatively new technique in semiconductor processing. CMP not only provides a method for copper removal and for forming patterned copper films but also addresses the increased need for local and global planarity in complex integrated circuit architectures.

Today, CMP is an essential step in the manufacture of almost every modern integrated circuit. According to the 1997 National Technology Roadmap for Semiconductors, the typical logic device in 2004 will include seven inner-layer dielectric (ILD) CMP steps, seven metal CMP steps and one shallow trench isolation (STI) CMP step. Put simply, CMP is quickly becoming a central aspect of semiconductor processing in the formation of integrated circuits.

CMP is a method of fabricating planar structures by the selective removal of topography-generating features. The CMP process involves the controlled removal of material on the wafer surface through the combined chemical and mechanical action of a slurry of abrasive particles and a polishing pad on the semiconductor wafer. The slurries used in CMP are best classified by the types of films they are intended to planarize. In semiconductor manufacturing, CMP processes are most commonly used for films comprised of silicon oxide, tungsten, copper, tantalum and titanium. CMP of copper films, for example, often employs slurries based with a complexing agent, which offers high copper ion solubility.

In addition to polishing of metallization layers, CMP processing generally also involves barrier layer and dielectric layer polishing. The dielectric layer is frequently comprised of an oxide material such as silica that forms the electrically insulating layer between conducting metal layers. A barrier layer is a layer disposed between two layers that prevent one layer from contaminating the other layer and vice versa. Copper metallization schemes often employ barrier metals such as tantalum or tantalum-rich alloys between the copper and dielectric layers to minimize cross-contamination between those layers. An integrated CMP processing technique should allow the polishing and planarization of alternating layers such as those described—e.g., a layer comprising copper on a layer comprising tantalum or Ta alloy, on a layer comprising oxide.

Following the CMP process, wafers are typically subjected to a post-CMP cleaning process to remove particulate and molecular contaminants before continuing the construction of the integrated circuit. For wafers processed in batches rather than individually, storage techniques are frequently used following the CMP process and prior to the post-CMP cleaning process. Storing the wafers frequently consists of placing them in a cassette filled with an appropriate liquid such as water.

For a variety of reasons, currently available CMP techniques are less than optimal. One reason is that the CMP process involves the use of small, abrasive particles that can prove difficult to remove from the wafer surface. Since, particles left on the wafer surface may cause circuit failure, techniques for slurry particles are desirable.

### BRIEF SUMMARY OF THE PREFERRED EMBODIMENTS

The preferred embodiments of the present invention include post chemical mechanical polishing (CMP) cleaning methods that reduce integrated circuit defects.

Some embodiments of the present invention involve the use of cleaning chemistries that facilitate the removal of particles from the wafer. This includes particles that are partially embedded in the previously applied corrosion inhibitor layers. Next, a corrosion inhibitor is applied while the wafers are in the post-CMP cleaning tool. Then the wafers are subsequently rinsed using deionized water and dried in anticipation of further manufacturing steps. By applying a corrosion inhibitor during the post-CMP cleaning step, openings in the original corrosion inhibitor layer left by removing partially embedded particles and debris are filled, which further reduces defets caused by corrosion. An advantage to this approach is that no additional equipment is necessary to apply the corrosion inhibitor because the corrosion inhibitor is applied to the wafer using the existing post-CMP clean tool. Another advantage is that applying the corrosion inhibitor during post-CMP clean relieves future time constraints associated with corrosion before the subsequent processing step.

In another embodiment, wafers that have had cleaning liquids applied subsequently have another corrosion inhibitor applied. When the exposed surface to be protected includes a material susceptible to degradation, the corrosion inhibitor used during post-CMP clean may comprise one or more passivation agents.

In yet another embodiment of the present invention, an additional chemistry is applied to the wafer after the corrosion inhibitor and before rinsing the wafer with deionized water. This allows excess amounts of the corrosion inhibitor to be removed leaving a monolayer of corrosion inhibitor for wafer protection.

### BRIEF DESCRIPTION OF THE DRAWINGS

For a more detailed description of the present invention, reference will now be made to the accompanying drawings, wherein:

FIG. 1A shows a dielectric with trenches formed therein;

FIG. 1B shows gross metal deposition used to fill the trenches of FIG. 1A;

FIG. 1C shows formed metal interconnects;

FIG. 2 shows a chemical mechanical polishing apparatus;

FIG. 3A shows a passivation layer containing slurry particles;

FIG. 3B shows the removal of the slurry particles of FIG. 3A;

FIG. 3C shows a failure resulting from corrosion; and

FIG. 4 shows data representing the improved methods of the preferred embodiments.

### DETAILED DESCRIPTION OF PREFERRED EMBODIMENTS

Manufacturing integrated circuits often involves a myriad of techniques used to provide metal interconnects to circuit elements on a semiconductor wafer. Among the chief concerns for metal interconnects is reliability, which is affected by many factors. Defective metal interconnects may result from corrosion of the metal, where contributing factors include: exposure to humidity, exposure to oxygen, temperature dependencies, and exposure time. The preferred embodiments of the present invention deal with employing a corrosion inhibitor, such as benzotriazole (BTA), during post-CMP cleaning. Post-CMP cleaning, in general, involves applying various chemistries to wafers either singularly or in batch format to clean off particulate matter from previous manufacturing steps. Preferably, the corrosion inhibitor is applied after a chemistry step has washed particles from the corrosion inhibitor applied during previous steps, like CMP. Subsequent rinsing is then performed using deionized water. Additionally, another chemistry may be used after the corrosion inhibitor and before the deionized water rinse so that the amount of corrosion inhibitor on the wafer may be controlled.

The term “semiconductor substrate” as used herein refers to a substrate comprised of a semiconductor material upon which an integrated circuit is being, will be or has been constructed. Typically, the substrate is in the form of a thin, circular wafer and therefore the term “wafer” as used herein refers synonymously to a semiconductor substrate. A variety of semiconductor materials are used in semiconductor processing such as silicon and gallium arsenide. Furthermore, other semiconductor materials exist and may be amenable to the methods and compositions disclosed herein. Therefore, without limiting the scope of the present invention, the preferred embodiments of the present invention involve a semiconductor substrate comprised of silicon. More preferably, the semiconductor substrate is a single-crystal silicon wafer. Furthermore, the term “semiconductor substrate” also encompasses a substrate comprised of a semiconductor upon which other materials have been deposited.

The term “surface material” as used herein refers to a material located at the surface of a semiconductor substrate. Because integrated circuit processing involves the deposition of patterned thin films on the semiconductor substrate, there will frequently be two or more surface materials on a semiconductor substrate. Consequently, references herein to “surface material” are not intended to imply a single surface material and instead refer to one or more particular surface materials.

The semiconductor processing industry has generally determined that barrier materials facilitate the construction of high-yield, high-reliability copper interconnects. As used herein, the term “barrier layer” is a layer disposed between two layers that prevent one layer from contaminating the other layer and vice versa. Barrier layers may be deposited by any manner over the surface of the semiconductor substrate and may be any other region that functions to protect one layer from an otherwise adjacent layer or vice versa. Barrier layers generally used in the semiconductor industry include, for example, tantalum nitride, titanium nitride, titanium/tungsten, tungsten, tantalum, composites thereof, and the like. Preferably, barrier layers are comprised of tantalum nitride when copper metallization is used. The barrier layer may be of any appropriate thickness. Preferably, the barrier layer is a few tens of angstroms to several hundred angstroms in thickness.

The use of materials with lower dielectric constants are desirable in that they may allow reduced capacitance between metal lines and therefore may also allow faster circuit operation. Air, or free space has a dielectric constant of approximately 1, and other materials are referenced with respect to air. For example, a material with a dielectric constant of 2 will have a dielectric constant that is twice the magnitude of air. The term “low-k” as used herein is intended to refer to dielectrics with dielectric constants below about 4.

Semiconductor Processing

Today's integrated circuits contain millions of circuit elements (i.e., transistors, resistors, capacitors, etc.) integrated on a substrate using semiconductor processing techniques. This substrate may comprise silicon, gallium arsenide, or any other suitable semiconducting material. Circuit elements integrated on the substrate are connected together by a series of metal interconnects, and often include multiple metal layers in order to facilitate connection in densely packed areas of the integrated circuit. While interconnections previously were made from aluminum, recent trends have pushed for the use of copper because of its lower resistance and lower susceptibility to metal migration. However, despite the advantages of using copper, from a semiconductor processing perspective copper is more difficult to implement. For example, removing excess aluminum using chemical etching techniques is easier than trying to remove excess copper using chemical etching techniques. Consequently, CMP techniques are often used to remove excess copper.

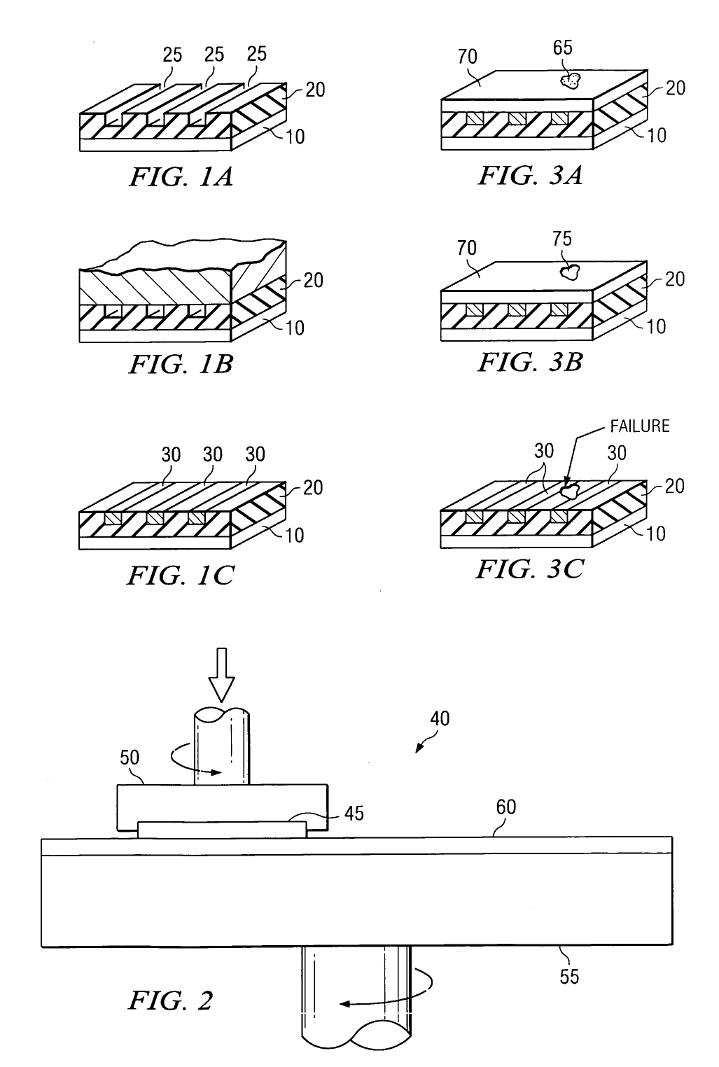

FIGS. 1A-1C depict an exemplary metal processing scheme on a substrate. Referring now to FIG. 1A, a substrate 10 is shown with an inner layer dielectric (ILD) 20 deposited on the substrate 10. Some conventional ILDs include organosilica glasses (OSGs) and/or doped silica such as fluorine-doped silica glasses (FSGs). Trenches 25 may be formed in the ILD 20 so that metal may later be used to fill them and create metal interconnects. Creating trenches in this manner and then back-filling them with metal is termed “damascene” construction. In filling the trenches, metal is grossly deposited across the ILD 20 as shown in FIG. 1B. Excess metal is then preferably removed so as to create metal interconnects 30 as shown in FIG. 1C. As described above, the current trend is to use copper to create metal interconnects while CMP techniques preferably are used in removing excess copper.

CMP Overview

In general, CMP involves pressing a semiconductor wafer against a moving polishing surface that is wetted with a chemically reactive, abrasive slurry. Conventional slurries are either acidic or basic, and generally contain either fumed or colloidal alumina, silica, zirconium oxide, magnesium oxide, or cerium oxide abrasive particles. The polishing surface usually is a planar pad made of a relatively soft, porous material such as polyurethane.

FIG. 2 depicts an apparatus 40 used in performing CMP on a semiconductor wafer 45. A wafer carrier 50 holds wafer 45 over a platen 55. The platen 55 includes a polishing pad 60 that contacts the wafer 45 as the wafer carrier 50 and the platen 55 rotate in opposite directions. The carrier 50 also allows slurry and/or other materials to be applied to the interface between wafer 45 and polishing pad 60. During operation, a predetermined down force is preferably applied to carrier 50 to achieve a desired polish pressure. Also during operation, carrier 50 is preferably rotated at a desired rate while platen 55 is preferably rotated in an opposing direction at a desired rate. Preferably, a slurry having a pH between about 3 and about 11 and comprised of slurry particles having an average diameter of between about 20 and about 200 nanometers (nm) is present during polishing. More preferably, the slurry particles are comprised of alumina. The combined action of the down force of carrier 50, the rotation of carrier 50 and platen 55 and polishing pad 60, and the chemical and mechanical effects of the slurry combine to polish the surface of wafer 45. Typically, CMP is performed for each metal layer that is processed, with current integrated circuits containing up to seven layers of metal.

During the course of integrated circuit processing—e.g., during CMP processing—both copper surfaces and barrier metal surfaces may be exposed. Differences in the galvanic potentials of the exposed metals can give rise to a type of corrosion in which the more easily oxidized metal is etched from the wafer surface. This phenomenon is frequently referred to as galvanic corrosion. Contributing factors to this corrosion include humidity, exposure to oxygen and exposure to ambient light. Because of its galvanic potential, copper is particularly susceptible to galvanic corrosion.

Corrosion can cause adjacent metal lines to grow, subsequently shorting together causing overall failure of the integrated circuit. The failure may be immediately noticed upon testing the integrated circuit after manufacture, this is called a “time-zero” failure. Alternately, the corrosion may not cause the integrated circuit to fail until it is accelerated by electric fields and changes in temperature that occur from typical operation. In either case, corrosion inhibits both short term and long term reliability of the integrated circuit.

Accordingly, after the polishing step of CMP, the wafers are transferred to a holding tank containing a mixture of deionized water and corrosion inhibitor, e.g., BTA. As shown in FIG. 3A, some of the slurry particles 65 prevent the formation of a uniform coating of corrosion inhibitor layer 70 in the holding tank as shown in FIG. 3A.

Post-CMP Clean

In accordance with the preferred embodiments of the present invention, wafers are cleaned using a post-CMP cleaning tool. In general, cleaning procedures are used throughout semiconductor manufacturing and although this disclosure focuses primarily on post-CMP cleaning, some of the embodiments may be used in other areas of semiconductor cleaning.

Post-CMP cleaning involves removing slurry and other particle debris resulting from previous manufacturing steps. Depending on the particular application, wafers may be cleaned together in the wafer “boat” or container, or they may be processed individually In either case, particulate matter such as slurry debris from CMP processes may be removed using the cleaning processes.

The cleaning liquids described in the preferred embodiments of the present invention may find application in any cleaning operation employed during semiconductor processing.

According to one preferred embodiment, the hydrophilic surface comprises a low-k dielectric comprised of an FSG. Other embodiments may include dielectrics with dielectric constants in the range of 1.4 to 3.7.

The constituents of the cleaning liquid may be mixed together in any order. Although preferably, surfactant is added to an aqueous liquid comprising the other components of the cleaning liquid. Ideally, the resulting solution is filtered before use using a 0.1 μm or better filter. The cleaning liquids employed in the preferred embodiments of the present invention are aqueous liquids. Such aqueous liquids may be low pH solutions having a pH less than 7 (the pH of pure water) and comprising one or more acidic components such as hydrochloric acid, acetic acid or citric acid. Alternatively, such aqueous liquids may also be high pH solutions having a pH greater than 7 and comprising one or more basic components such as tetramethylammonium hydroxide. Such aqueous liquids may also be neutral pH solutions having a pH of approximately 7 and comprising either no acidic or basic components or alternatively, comprising both acidic and basic components whose combined effect is to retain a pH of approximately 7.

During CMP, wafers are coated with a corrosion inhibitor, like BTA, so that wafer defects are minimized. This typically happens in a holding tank of the CMP tool, which contains deionized water and BTA. During CMP the corrosion inhibitor can also be applied on the platen 55 especially in an integrated polishing and cleaning tool which does not have a holding tank. After CMP, the wafers are subsequently cleaned in a post-CMP clean step leaving an opening 75 in the BTA layer as shown in FIG. 3B. Openings in the BTA layer may vary depending on the size of the particle 65. Larger particles may create larger openings that may render the substrate susceptible to corrosion and possible interconnect failures after the BTA layer is removed for further processing as shown in FIG. 3C. Depending on the size of the slurry particles, with average diameters between about 20 and about 200 nm, the resulting corrosion may be enough to cause a time-zero failure or alternately cause the failure to occur while the integrated circuit is in use.

In a preferred embodiment, the post-CMP cleaning step includes applying cleaning liquids to the wafers thereby causing particles to be removed. This includes particles partially embedded in the previously applied corrosion inhibitor layers. Next, a corrosion inhibitor is applied while the wafers are in the post-CMP cleaning tool. Then the wafers are subsequently rinsed using deionized water and dried in anticipation of further manufacturing steps. By applying a corrosion inhibitor during the post-CMP cleaning step, openings in the original corrosion inhibitor layer left by removing embedded particles and debris are filled, which further reduces defects caused by corrosion. This process may be implemented using batch processing tools, or the process may be implemented using single wafer processing tools such as the “Momentum” tool by Novelus, the “Mirror Mesa” and the “Reflection” tools by Applied Materials, as well as similar tools made by Ebara. Also, the corrosion inhibitor may be applied in megasonic, spin rinse dry, or brush scrub boxes.

In one embodiment, wafers that have had cleaning liquids applied subsequently have another corrosion inhibitor applied. When the exposed surface to be protected includes a material susceptible to degradation such as by galvanic corrosion, the corrosion inhibitor used during post-CMP clean may comprise one or more passivation agents. Preferably, if the surface includes a copper surface material, the corrosion inhibitor is BTA and is present at a concentration of between approximately 1 ppm and 1000 ppm by weight. Most preferably the concentration is 8 ppm by weight. Suitable BTA products include REPSX01-C from Sumitomo, or Cu-Protect330 from Air Liquide. Note that the BTA products are preferably diluted at least twice before application to the wafers. For example, BTA may be diluted with deionized water from 30,000 ppm to 300 ppm (by weight) before being placed in the distribution system. Once the BTA is placed in the distribution system and delivered to the post-CMP cleaning tool, the BTA may be further diluted to achieve a desired concentration of 8 ppm by weight.

The temperature at which the corrosion inhibitor is applied is preferably between about 25° C. and 500° C. The duration of applying the corrosion inhibitor preferably is between about 5 seconds and 5 minutes, with 60 seconds being most preferred. Also, the pH of the corrosion inhibitor solution preferably is between about 4.0 and 10, with a pH of about 8 being most preferred.

The advantage to this approach is that no additional equipment is necessary to apply the corrosion inhibitor because the corrosion inhibitor is applied to the wafer using the existing post-CMP clean tool. Also, manufacturing steps that come after the post-CMP cleaning steps sometimes require the wafers to sit idle for up to six hours, which allows undesirable corrosion to occur. This corrosion begins to occur immediately after the slurry particles are removed from the corrosion inhibitor layer, and so applying the corrosion inhibitor during post-CMP clean relieves future time constraints associated with corrosion.

Another embodiment of the present invention includes an additional chemistry applied to the wafer after the corrosion inhibitor and before rinsing the wafer with deionized water. Preferably this additional chemistry is a basic chemistry such as tetramethylammonium hydroxide. Applying a chemistry in this manner allows excess amounts of the corrosion inhibitor to be removed leaving a monolayer of corrosion inhibitor for wafer protection.

The term “ultrasonic” as used herein includes megasonic cleaning, which generally comprises not only of high-frequency mechanical vibrations, but also the application of a shearing force caused by directed beams that run parallel to the silicon surface. It should be noted that the preferred embodiments do not require the use megasonic cleaning methods in the corrosion inhibit or deionized water rinse steps.

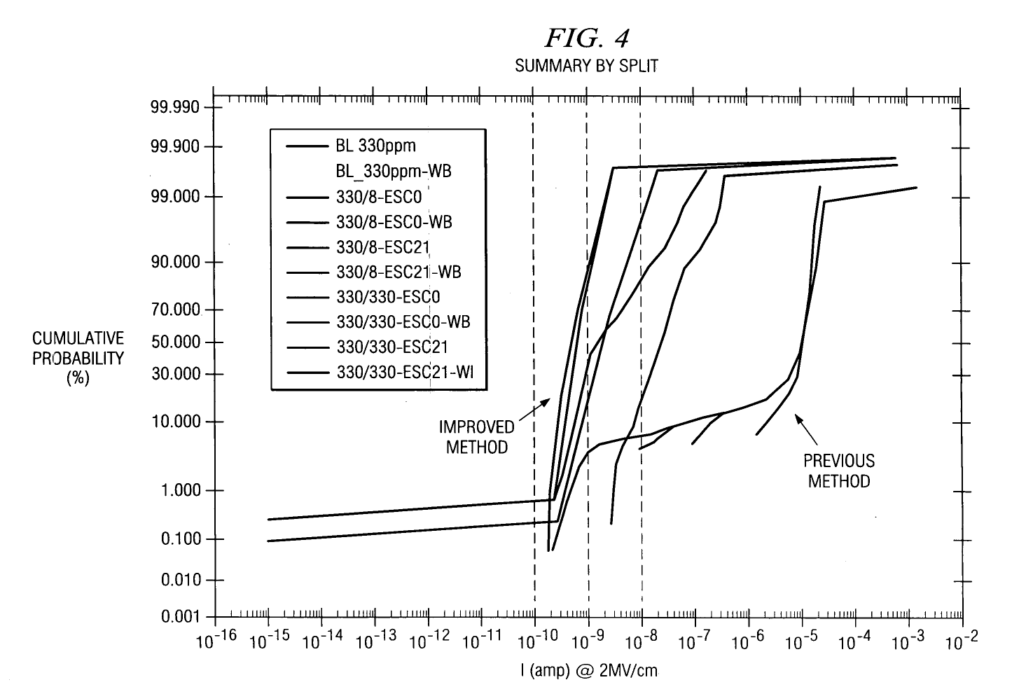

Referring now to FIG. 4, leakage current measurements were taken on sample wafers containing 20,000 pairs of metal interconnects, where the metal interconnects are separated by 0.175 μm and have an electric field of 2 MV/cm. The sample wafers were subjected to 100% humidity environment for 12 hours after post CMP clean and before the subsequent processing steps, where attaining the lowest leakage possible is desirable. The data labeled “improved method” in FIG. 4 represents the measurements taken from a sample wafer which underwent post-CMP cleaning according to the preferred embodiments, which includes application of a corrosion inhibitor. Likewise, the data labeled “previous method” in FIG. 4 represents the measurements taken from a sample wafer which did not have a corrosion inhibitor applied during post-CMP clean. Note that there is at least a 1.5 order of magnitude decrease in the measured leakage current between metal lines.

While the preferred embodiments of the present invention have been shown and described, modifications thereof can be made by one skilled in the art without departing from the spirit and teachings of the invention. The embodiments described herein are exemplary only, and are not intended to be limiting. Many variations and modifications of the invention disclosed herein are possible and are within the scope of the invention.

Accordingly, the scope of protection is not limited by the description set out above, but is only limited by the claims which follow, that scope including all equivalents of the subject matter of the claims. Each and every claim is incorporated into the specification as an embodiment of the present invention. Thus the claims are a further description and are an addition to the preferred embodiments of the present invention. Use of the term “optional” with respect to any element of a claim is intended to mean that the subject element is required, or alternatively, is not required. Both alternatives are intended to be within the scope of the claim. The discussion of a reference in the Description of Related Art, if any, is not an admission that it is prior art to the present invention, especially any reference that may have a publication date after the priority date of this application.. The disclosures of all patents, patent applications and publications cited herein are hereby incorporated herein by reference, to the extent that they provide exemplary, procedural or other details supplementary to those set forth herein.

1-18. (canceled)

19. A semiconductor substrate made by the process comprising:
(a) applying a first passivation layer to the semiconductor substrate;
(b) applying a first chemistry to the semiconductor substrate; and
(c) applying a second passivation layer to fill openings created in the first passivation layer by the first chemistry.

20. The process of claim 19, wherein (a)-(c) occur following a chemical mechanical polishing (CMP) process in which the first passivation layer was applied.

21. The process of claim 20 wherein, a surface of the semiconductor substrate comprises silica.

22. The process of claim 21, wherein the silica further comprises a low-k dielectric.

23. The process of claim 22 wherein the low-k dielectric has a dielectric constant in the range of about 1.4 to about 3.7.

24. The process of claim 23, wherein the silica includes FSGs.

25. The method of claim 23, wherein the silica includes OSGs.

26. The process of claim 20, wherein a surface of the semiconductor substrate comprises copper.

27. The process of claim 20, wherein the concentration the second passivation layer is between about 1 ppm to 1,000 ppm by weight.

28. The process of claim 20, wherein the concentration of second passivation layer is about 8 ppm.

29. The process of claim 20, wherein the pH of the second passivation layer solution is between about 4.0 and 10.

30. The process of claim 29, wherein the pH is about 8.

31. The process of claim 30, wherein the temperature at which the second passivation layer is applied is between about 250° C. and 500° C.

32. The process of claim 31, wherein the duration of applying the second passivation layer is between about 5 seconds and 5 minutes.

33. The process of claim 32, wherein the duration is about 60 seconds.
